(19) United States
(12) Patent Application Publication
(10) Pub. No.: US 2026/0143763 A1
(43) Pub. Date: May 21, 2026

(54) SEMICONDUCTOR DEVICE WITH AIR GAP AND MANUFACTURING METHOD THEREOF

(71) Applicant: Taiwan Semiconductor Manufacturing Company, Ltd., Hsinchu (TW)

(72) Inventors: Zi Yi YANG, Hsinchu (TW); Ting-Ya LO, Hsinchu (TW); Hsu-Wei LIU, Hsinchu (TW); Hsin-Yen HUANG, Hsinchu (TW); Hsiao-Kang CHANG, Hsinchu (TW)

(73) Assignee: Taiwan Semiconductor Manufacturing Company, Ltd., Hsinchu (TW)

(21) Appl. No.: 18/952,150

(22) Filed: Nov. 19, 2024

(51) Int. Cl. H01L 29/06; H01L 21/321; H01L 21/768

(52) U.S. Cl. CPC H10D 62/115; H10P 52/403; H10W 20/072; H10W 20/46

(57) ABSTRACT

A method for manufacturing a semiconductor device is provided, including the following steps. A plurality of conductive features extending upward is formed in a normal direction of a substrate. A sacrificial layer is formed in the grooves between the conductive features. An upper portion of the sacrificial layer is removed to expose the conductive features. A sustaining layer is formed to cover a lower portion of the sacrificial layer and the conductive features. The lower portion of the sacrificial layer is removed to form at least an air gap defined by the sustaining layer and the conductive features.

### BACKGROUND

With rapid development of semiconductor technology, the integration density of various electronic components, such as transistors, diodes, resistors, capacitors, etc., is being continuously improved by continual reduction in minimum feature sizes. As the feature sizes decrease, the distance between metal features is continually reduced, which increases the resulting parasitic capacitance between the metal features, thereby leading to higher power consumption and larger resistance-capacitance (RC) time delay for an integrated chip. There is continuous demand to develop a structure and/or a method to incorporate a lower parasitic capacitance into the semiconductor devices so as to isolate the metal features and to reduce line-to-line capacitance and the RC time delay.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 10 illustrate schematic diagrams of various stages of a method for manufacturing a semiconductor device according to an embodiment of the present disclosure.

FIG. 11 is a schematic diagram of materials used to form a sustaining layer according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

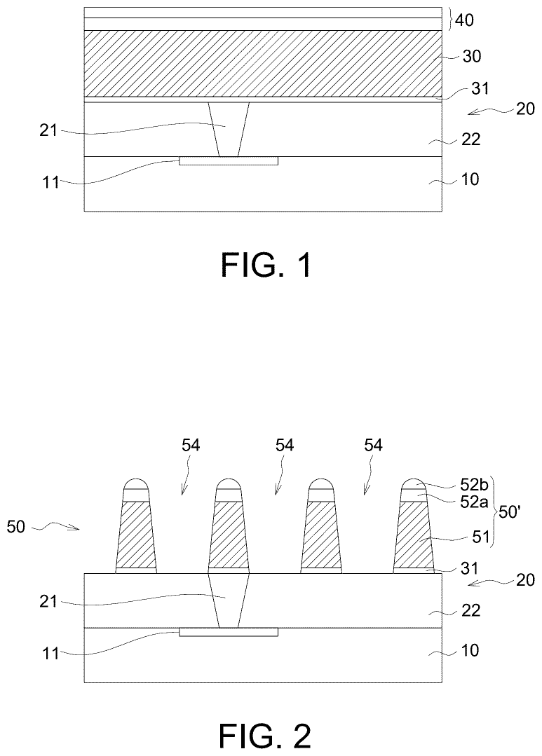

The present disclosure relates to a semiconductor device and a method for manufacturing the semiconductor device. FIGS. 1 to 10 illustrate some schematic diagrams of various stages of a method for manufacturing a semiconductor device 100 according to an embodiment of the present disclosure. However, additional steps may be provided before, after, or during various stages of the method, and some of the steps described herein may be replaced by other steps or eliminated. Similarly, additional features may be present in semiconductor device 100 and/or features presented herein may be replaced or eliminated in additional embodiments.

Referring to FIG. 1, a metal layer 30 is deposited on a substrate 10. The metal layer 30 may be deposited on a first interconnect layer 20 formed over the substrate 10.

In some embodiments, the substrate 10 may be a semiconductor substrate, such as an element semiconductor or a compound semiconductor. One of element semiconductors is composed of single atoms, such as silicon (Si), germanium (Ge) or the like in the fourth column of the periodic table. One of compound semiconductors is composed of two or more elements, such as silicon carbide (SiC), gallium arsenide (GaAs), gallium phosphide (GaP), indium phosphide (InP), indium arsenide (InAs), and indium antimonide (InSb), gallium indium phosphide (GaInP), gallium indium arsenide phosphide (GaInAsP) or the like. The compound semiconductors can have gradient characteristics in which their composition changes from one ratio at one location in the compound semiconductor to another ratio at another location. Compound semiconductors can be formed on silicon substrates. Compound semiconductors can be strained. Alternatively, the substrate 10 may include non-semiconductor materials such as glass, fused silica, calcium fluoride, or the like. Additionally, in some embodiments, the substrate 10 may be a semiconductor-on-insulator (SOI) (e.g., silicon germanium-on-insulator (SGOI)). Generally, the SOI substrate includes a layer of semiconductor material, such as epitaxial silicon (Si), germanium (Ge), silicon germanium (SiGe) or a combination thereof. The substrate 10 may be doped with p-type dopants, such as boron (Br), aluminum (Al), gallium (Ga), etc., or may be selectively doped with n-type dopants, as is known in the art. In some embodiments, the substrate 10 may include a doped epitaxial layer. Shallow trench isolation (STI) regions (not shown) may be formed in the substrate 10 to isolate active regions, such as source or drain regions of an integrated circuit device 11 in the substrate 10.

In some embodiments, the integrated circuit device 11 may include a complementary metal oxide semiconductor (CMOS) transistor, a planar or vertical multi-gate transistor (such as a FinFET device), a gate-all-around (GAA) device, a resistor, capacitors, diodes, transistors (such as field effect transistors), interconnects, etc., based on practical applications. Additionally, via holes (not shown) may be formed extending into the substrate 10 for electrically connecting components on opposite sides of the substrate 10.

A first interconnect layer 20 is formed over the substrate 10 with at least one conductive interconnect 21 (e.g., a conductive via contact). As shown in FIG. 1, the conductive interconnect 21 extends from the top surface to the bottom surface of dielectric layer 22. The dielectric layer 22 may include spin-on glass (SOG), amorphous fluorocarbon, fluorinated silica glass (FSG), carbon-doped silicon oxide (e.g., SiCOH), xerogel, aerogel, polyimide, parylene, bisbenzocyclobutene (BCB), non-porous materials, porous materials or combinations thereof. In some embodiments, the dielectric layer 22 may include a high density plasma (HDP) dielectric material (e.g., HDP oxide), a high aspect ratio process (HARP) dielectric material (e.g., HARP oxide), or a combination thereof.

At least one conductive interconnect 21 includes conductive materials, such as but not limited to copper (Cu), cobalt (Co), ruthenium (Ru), molybdenum (Mo), chromium (Cr), tungsten (W), rhodium (Rh), iridium (Ir), nickel (Ni), palladium (Pd), platinum (Pt), silver (Ag), gold (Au), aluminum (Al) or alloys thereof. In some embodiments, the conductive material may be provided as multiple layers of different compositions.

The metal layer 30 can be deposited on the first interconnect layer 20 through an appropriate deposition process known in the semiconductor manufacturing field, such as but not limited to physical vapor deposition (PVD), chemical vapor deposition (CVD), atomic layer deposition (ALD), plasma enhanced CVD (PECVD), plasma enhanced ALD (PEALD), etc. In some embodiments, the metal layer 30 is made of a conductive material, such as, but not limited to, Cu, Co, Ru, Mo, Cr, W, Mn, Rh, Ir, Ni, Pd, Pt, or alloys thereof. In some embodiments, a glue layer 31 may be deposited on the first interconnect layer 20 by a suitable process known in the semiconductor manufacturing field, such as, but not limited to, PVD, CVD, ALD, PECVD, or the like. The glue layer 31 can provide good adhesion to the first interconnect layer 20 and the metal layer 30. The glue layer 31 can be made of a nitride of tantalum (Ta), titanium (Ti), or other suitable metals.

In FIG. 1, a mask layer 40 (e.g., a hard mask layer) is deposit on the metal layer 30, such as silicon, silicon oxynitride, silicon carbonitride, silicon carbonitride oxycarbon, cobalt, ruthenium, tungsten, tungsten nitride, carbon tungsten, titanium nitride, zirconium oxide, aluminum oxide, yttrium oxide, aluminum oxynitride, hafnium oxide, hafnium zirconium oxide, hafnium silicon oxide, hafnium silicon oxynitride, silicon zirconium oxide, silicon zirconium oxide, hafnium aluminum oxide, nitrogen Hafnium aluminum oxide, aluminum zirconia, ytterbium oxide or combinations thereof. In some embodiments, the mask layer 40 may have a thickness of about 300 Angstroms to about 500 Angstroms. The mask layer 40 may be deposited on the metal layer 30 by a suitable process known in the semiconductor manufacturing field, such as PVD, CVD, ALD, PEALD, thermal ALD, PECVD, etc.

A photoresist layer (not shown) is formed on the mask layer 40. The photoresist layer is then patterned using suitable photolithography techniques to form a pattern of vias. For example, the photoresist layer is exposed to pattern and then developed to form a pattern of via holes. Using a suitable etching process, such as but not limited to a wet etching process, a dry etching process, or a reactive ion etching (RIE) process, the pattern of the via holes formed in the photoresist layer is transferred to the mask layer 40. After the pattern of the via holes is transferred to the mask layer 40, the photoresist layer can be removed through, for example but not limited to, an ashing process.

The via pattern formed in the mask layer 40 is then transferred to the metal layer 30 to form a patterned layer 50 including a plurality of features 50′. The patterned layer 50 is formed by using appropriate etching processes such as but not limited to RIE, plasma etching, deep RIE, atomic layer etching, etc., and etching gases such as but not limited to CH₃COOH, CH₃OH, CH₃CH₂OH, CH₃F, CHF₃, CH₂F₂, CF₄, C₄F₈, C₄F₆, N₂, Ar, O₂, NF₃, CO₂, Hz, Cl₂, SiCl₄, BCl₃, etc. are used to form the patterned layer 50. The conductive features 51 of each feature 50 are spaced apart from each other in the horizontal direction by grooves 54.

The plurality of conductive features 51 extend upward from the first interconnect layer 20 along the normal direction of the substrate 10 and are spaced apart from each other in the horizontal direction. The patterned layer 50 includes a conductive feature 51 disposed on the first interconnect layer 20 and at least one of shielding features 52a and 52b disposed on the conductive feature 51. The conductive feature 51 is electrically connected to at least one integrated circuit element 11 disposed below the first interconnect layer 2 through at least one conductive interconnect 21.

In some embodiments where the metal layer 30 is patterned through a deep RIE process (e.g., an inductively coupled plasma reactive ion etching (ICP-RIE) process), the following conditions may be used alone or in combination: (1) transformer coupled plasma (TCP) power: about 100 W to about 1500 W, bias voltage: about 0V to about 300V, and gas: CH₃COOH, CH₃OH, CH₃CH₂OH or other organic gases, or combinations thereof; (2) TCP power: about 100 W to about 150 0W, bias voltage: about 0V to about 500V, and gas: CF₄, CHF₃, CH₂F₂, CH₃F, C₄F₈, C₄F₆, N₂, O₂, Ar or a combination thereof; (3) TCP power: about 100 W to about 2000 W, bias voltage: about 0V to about 500V, and gas: Cl₂, SiCl₄, BCl₃, CF₄, CHF₃, CH₂F₂, CH₃F, C₄F₈, C₄F₆, N₂, O₂. Ar or a combination thereof.

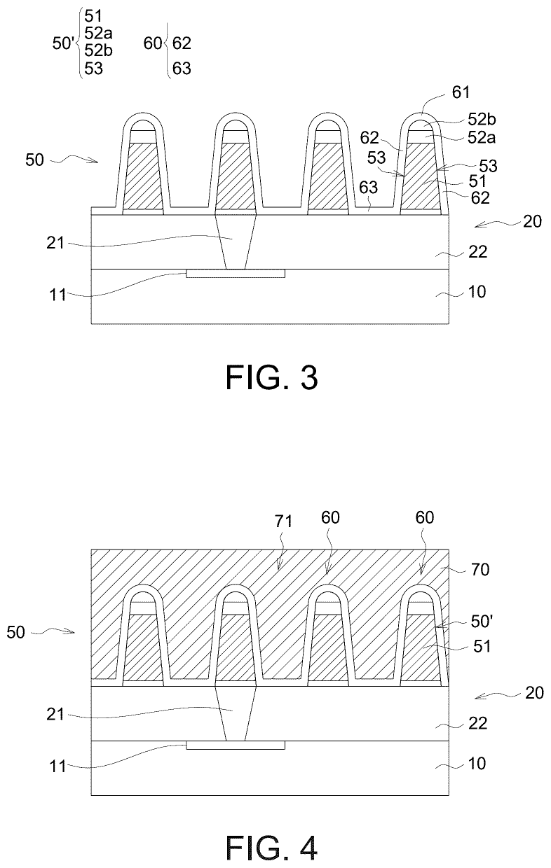

Referring to FIG. 3, a dielectric material is deposited on the patterned layer 50 to form a capping layer 60 on each of the features 50′. The capping layer 60 includes a top 61 disposed on the top surface of the shielding feature 52b, two opposite wall portions 62 extending downward from opposite ends of the top 61 to cover the opposite side surfaces 53 of the conductive feature 51, and a bottom 63 connecting to the bottom side of the two opposite wall portions 62. In some embodiments, the dielectric material of the capping layer 60 includes, for example, but not limited to, silicon nitride (SiN), silicon oxide (SiO), silicon carbide (SiC), silicon carbonitride (SiCN), silicon oxynitride (SiON), carbon oxide Silicon (SiC) or a combination thereof.

In some embodiments, the reactant materials used in the deposition process to form the capping layer 60 may include, for example, but not limited to, silane (SiH₄), oxygen (O₂), tetraethylorthosilicate (TEOS), Ammonia (NH₃), nitrous oxide (N₂O) or combinations thereof. In some embodiments, the deposition process may be performed by ALD, CVD, PEALD, PECVD or the like.

Next, referring to FIG. 4, a sacrificial layer 70 is formed to cover the patterned layer 50 and the capping layer 60. As shown in FIG. 4, a sacrificial material is filled into the grooves 54 formed between conductive features 51 to form the sacrificial layer 70. The top surface of the sacrificial layer 70 thus formed may be higher than the top 61 of the capping layer 60.

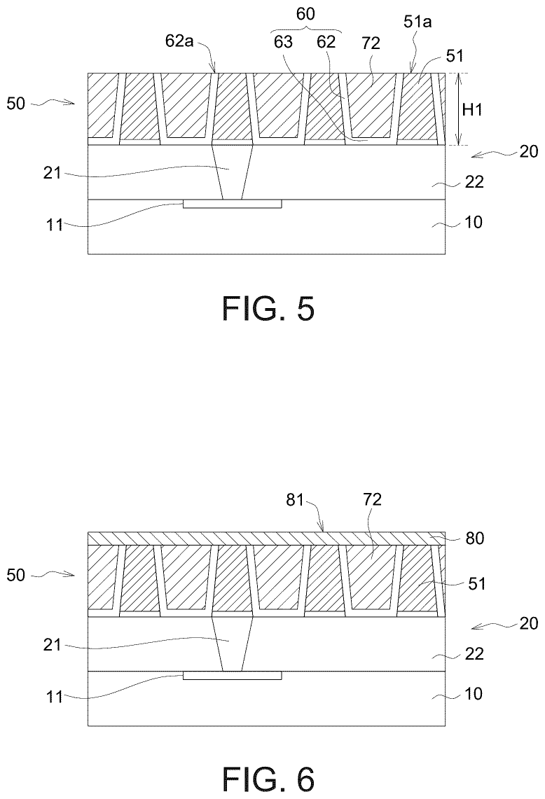

Referring to FIG. 5, a suitable planarization process, such as but not limited to chemical mechanical planarization (CMP), is performed to remove the upper portion 71 of the sacrificial layer 7, the top 61 of the capping layer 6 and the shielding features 52a and 52b of the patterned layer 50 until the top surface 51a of conductive feature 51 and the top surface 62a of the two opposite wall portions 62 are exposed. The lower portion 72 of the sacrificial layer 70 is not removed, so that the height H1 of the lower portion 72 of the sacrificial layer 70 is substantially the same with the height H1 of the planarized conductive feature 51. In addition, the top 61 of the capping layer 60 is also removed, leaving only the two opposite wall portions 62 and the bottom 63 of the capping layer 60 in the groove 54.

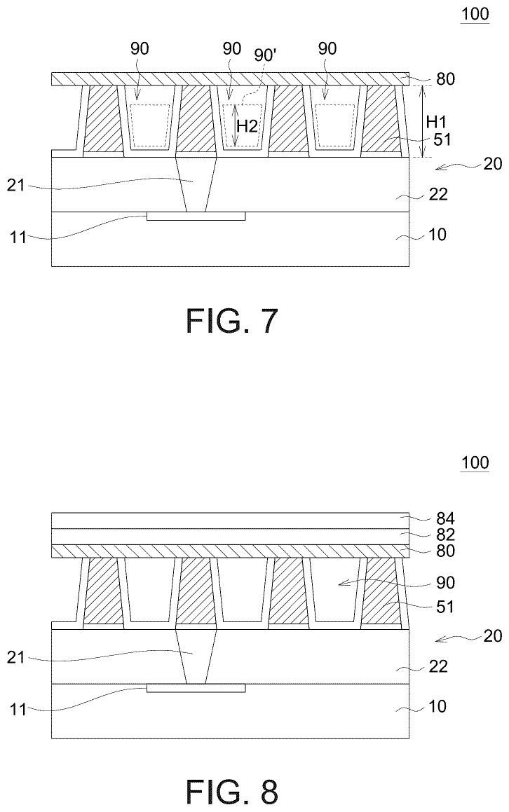

Referring to FIG. 6, a sustaining layer 80 is formed on the conductive features 51 and the lower portion 72 of the sacrificial layer 70 by spin-on process. The top surface 81 of the sustaining layer 80 is not coplanar with the top surfaces 51a of the conductive features 51 and the top surfaces 62a of the two opposite wall portions 62 of the capping layer 60. The deposition of the low-k dielectric material used to form the sustaining layer 80 may be performed by a suitable deposition process known to those skilled in the semiconductor manufacturing art, such as, but not limited to, ALD, CVD, PEALD, PECVD, or the like. Examples of low-k dielectric materials suitable for forming the sustaining layer 80 include, but are not limited to, silicon oxide, silicon nitride, silicon carbide, silicon oxycarbide, silicon oxynitride, silicon carbonitride, silicon oxynitride, or a combination thereof. In addition, the material used to form the sustaining layer 80 may be graphite oxide, which may provide better mechanical strength to maintain the air gaps 90 formed in the subsequent process (see FIG. 7). In one embodiment, the thickness of the graphite oxide used to form the sustaining layer 80 may range from about 2 angstroms to about 100 angstroms.

Referring to FIG. 7, the lower portion 72 of the sacrificial layer 70 is removed to form at least one air gap 90. The sustaining layer 80 can cover each of the conductive features 51 and be horizontally supported between the top surfaces of the plurality of conductive features 51 so that the volume of the air gap 90 is relatively large than that of conventional air gap 90′. The lower portion 72 of the sacrificial layer 70 is removed, for example by diffusion through the porous structure formed in the sustaining layer 80, to obtain the semiconductor device 100 having the air gap 90 defined by the sustaining layer 80 and the conductive features 51. In some embodiments, the sacrificial layer 70 may be removed by a treatment including an annealing treatment, a plasma treatment, a ultraviolet treatment, or a combination thereof. For example, an annealing process at an appropriate temperature is performed to allow the lower portion 72 of the sacrificial layer 70 to evaporate and to degas through the sustaining layer 80.

In FIG. 7, compared with the air gap 90′ (indicated by a dotted line) conventionally formed in a semiconductor device, the volume of the air gap 90′is smaller than the volume of the air gap 90. That is, the height H2 in the air gap 90′ is smaller than the height H1 in the air gap 90. This is due to the material forming the sustaining layer 80 (such as graphite oxide) can provide better mechanical strength to maintain the subsequently formed air gaps 90, so that each of the air gaps 90 formed in the semiconductor device 100 according to the present disclosure has an increased volume. The height H1 formed by the sustaining layer 80 in each air gap 90 is substantially the same with the height H1 of the conductive feature 51. Therefore, the capacitance of the conductive feature 51 (i.e., the first metallization layer) can be reduced, and thus the RC time delay can be reduced. The semiconductor device 100 according to the present disclosure is more effective in applications requiring metal lines with denser and smaller pitches.

Referring to FIG. 8, at least one of etch stop layers (ESL) 82 and 84 is formed on the sustaining layer 80. The etching stop layers 82 and 84 are formed by CVD, PECVD, ALD, PEALD or the like. Materials suitable for forming the etch stop layers 82 and 84 may include, but are not limited to, aluminum compounds (such as aluminum nitride, aluminum oxynitride, aluminum oxide, etc.), silicon compounds (such as silicon oxycarbide, silicon carbonitride, silicon compounds), silicon oxynitride, silicon oxide, silicon carbide, silicon oxynitride or combinations thereof.

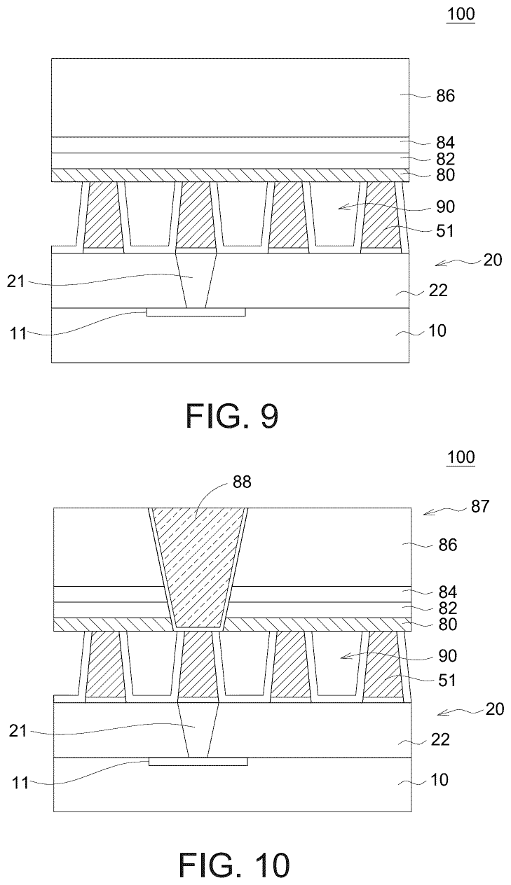

Next, referring to FIG. 9, an interlayer dielectric (ILD) layer 86 is formed on the etching stop layers 82 and 84. ILD layer 86 may include dielectric materials such as, but not limited to, silicon oxide, silicon nitride, silicon oxynitride, spin-on glass (SOG), amorphous fluorocarbon, fluorinated quartz glass (FSG), carbon-doped silicon oxide. In some embodiments, the interlayer dielectric layer 86 may include a high density plasma (HDP) dielectric material (e.g., HDP oxide), a high aspect ratio process (HARP) dielectric material (e.g., HARP oxide), or a combination thereof.

Referring to FIG. 10, at least one conductive interconnect structure (e.g., conductive via contact) 88 is formed in the interlayer dielectric layer 86 to obtain the second interconnect layer 87. The conductive interconnect structure 88 is connected to at least one conductive feature 51. In some embodiments, formation of at least one conductive interconnect structure 88 includes the following steps. First, at least one via opening is formed through the interlayer dielectric layer 86, the etch stop layers 82 and 84 and the sustaining layer 80 to expose at least one conductive feature 51 from the at least one via opening. After forming at least one via opening, at least one conductive interconnect structure 88 is formed by depositing metal material in the at least one via opening, and then remove excess metal material through planarization technology such as CMP. In some embodiments, the metal materials may include, for example, but not limited to, Cu, Co, Ru, Mo, Cr, W, Mn, Rh, Ir, Ni, Pd, Pt, Ag, Au, Al, or alloys thereof. In some embodiments, the deposition of metal materials used to form the conductive interconnect structure 88 may be performed by suitable techniques known to those skilled in the semiconductor manufacturing art, such as, but not limited to, PVD, CVD, PECVD, ALD, PEALD, or other suitable deposition techniques.

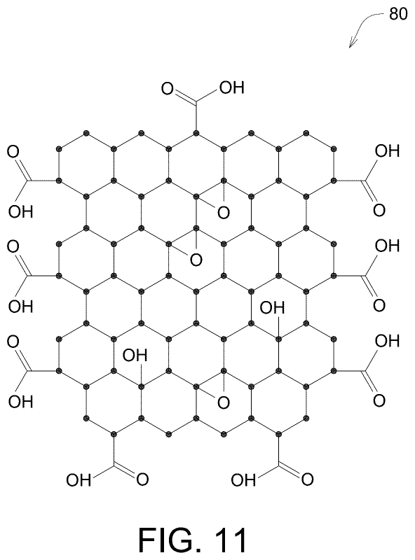

The components and structure of graphene oxide forming the sustaining layer 80 is shown in FIG. 11. Graphene is a two-dimensional crystalline allotrope made of pure carbon atoms with a hexagonal lattice structure. Graphene is known for its unique properties, including high optical transparency, optimal thermal conductivity at room temperature, and the ability to be flexible within a strong, nanometer-sized material.

Graphene oxide (GO) happens to be an important precursor to obtain graphene with higher yield and lower cost. To obtain GO, graphite oxide is first produced using graphite crystals that have been oxidized by strong oxidants such as sulfuric acid. Through ultrasonic treatment, graphite adopts oxygen-containing functional groups, allowing the material to be dispersed in water while increasing the distance between layers. The graphite oxide can then be exfoliated into single or multilayer oxygen-functionalized graphene oxide (GO), as shown in FIG. 11.

Graphene oxide is a single-layer insulating material composed of carbon, hydrogen and oxygen molecules. One of important features of GO is that it can be produced using graphite through different chemical methods, achieving high yields with excellent cost-effectiveness. The second feature is that GO is very dispersed in water and can form stable hydrocolloids for the assembly of macrostructures through cheaper solution processes. Therefore, GO is an oxidized version of graphene, consisting of oxygen-containing groups. In some embodiments, GO can be synthesized in different ways such as the modified Hummer's method and Staudenmaier method.

The present disclosure is directed to a semiconductor device with air gap and a method for manufacturing the semiconductor device. The sacrificial layer could be an organic layer and composed of C, O, N, H; and the height of the sacrificial layer could be tuning by CMP, thermal recess or etching back process, and it could be removed by thermal baking and/or UV curing process. In addition, the material forming the sustaining layer (such as graphene oxide) could be composed of C and O; it could provide good mechanical strength to keep robust of air-gap structure, and is performed by spin-on process. The graphene oxide can be used to form a full air-gap rather than a partial air gap (the air/dielectric ratio of the partial air gap is 7:3, for example), and thus the full air-gap has the benefit of reducing parasitic capacitance, which can enhance the functionality of microelectronic devices.

According to some embodiments of the present disclosure, a method for manufacturing a semiconductor device is provided, including the following steps. A patterned layer including a plurality of features is formed on a substrate, and each of the features includes a conductive feature and a shielding feature extending upward in a normal direction of the substrate. A dielectric material deposited on the patterned layer to form a capping layer on each of the features, the capping layer including a top and two opposing wall portions disposed on each of the features. A sacrificial layer is formed in grooves between the features. The upper portion of the sacrificial layer, the top of the capping layer, and the shielding features are removed to expose the conductive features. A sustaining layer is formed to cover a lower portion of the sacrificial layer and the conductive features. The lower portion of the sacrificial layer is removed to form at least an air gap defined by the sustaining layer and the conductive features.

According to some embodiments of the present disclosure, a method for manufacturing a semiconductor device is provided, including the following steps. A plurality of conductive features extending upward is formed in a normal direction of a substrate. A sacrificial layer is formed in the grooves between the conductive features. An upper portion of the sacrificial layer is removed to expose the conductive features. A sustaining layer is formed to cover a lower portion of the sacrificial layer and the conductive features. The lower portion of the sacrificial layer is removed to form at least an air gap defined by the sustaining layer and the conductive features.

According to some embodiments of the present disclosure, a semiconductor device including a substrate, a patterned layer and a sustaining layer is provided. The patterned layer is disposed on the substrate. The patterned layer includes a plurality of conductive features extending upward in a normal direction of the substrate. The sustaining layer covers the conductive features and is horizontally supported between the conductive features to form an air gap defined by the sustaining layer and the conductive features.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a patterned layer including a plurality of features on a substrate, each of the features including a conductive feature and a shielding feature extending upward in a normal direction of the substrate;
depositing a dielectric material on the patterned layer to form a capping layer on each of the features, the capping layer including a top and two opposing wall portions disposed on the features;
forming a sacrificial layer in grooves between the conductive features;
removing an upper portion of the sacrificial layer, the top of the capping layer and the shielding features to expose the conductive features;
forming a sustaining layer to cover a lower portion of the sacrificial layer and the conductive features; and
removing the lower portion of the sacrificial layer to form at least an air gap defined by the sustaining layer and the conductive features.

2. The method of claim 1, wherein the shielding feature is disposed on top of the conductive feature, and when the upper portion of the sacrificial layer is removed, the shielding feature is removed to retain the conductive feature in the sacrificial layer.

3. The method of claim 2, wherein removing the upper portion of the sacrificial layer includes chemical mechanical polishing.

4. The method of claim 1, wherein the lower portion of the sacrificial feature is removed by a treatment including an annealing treatment, a plasma treatment, an ultraviolet treatment, or a combination thereof.

5. The method of claim 1, wherein a material used to form the sustaining layer includes graphite oxide.

6. The method of claim 5, wherein a thickness of the sustaining layer is between 2 angstroms and 100 angstroms.

7. The method of claim 1, wherein the sustaining layer maintains a height in the air gap that is same with a height of the conductive feature.

8. A method for manufacturing a semiconductor device, comprising:
forming a plurality of conductive features extending upward in a normal direction of a substrate;
forming a sacrificial layer in grooves between the conductive features;
removing an upper portion of the sacrificial layer to expose the conductive features;
forming a sustaining layer to cover a lower portion of the sacrificial layer and the conductive features; and
removing the lower portion of the sacrificial layer to form at least an air gap defined by the sustaining layer and the conductive features.

9. The method of claim 8, wherein removing the upper portion of the sacrificial layer includes chemical mechanical polishing.

10. The method of claim 8, wherein the lower portion of the sacrificial feature is removed by a treatment including an annealing treatment, a plasma treatment, an ultraviolet treatment, or a combination thereof.

11. The method of claim 8, wherein a material used to form the sustaining layer includes graphite oxide.

12. The method of claim 11, wherein a thickness of the sustaining layer is between 2 angstroms and 100 angstroms.

13. The method of claim 8, wherein the sustaining layer maintains a height in the air gap that is same with a height of the conductive feature.

14. A semiconductor device, comprising:
a substrate;
a patterned layer disposed on the substrate, the patterned layer includes a plurality of conductive features extending upward in a normal direction of the substrate; and
a sustaining layer covering the conductive features and horizontally supported between the conductive features to form at least an air gap defined by the sustaining layer and the conductive features.

15. The semiconductor device of claim 14, wherein a material of the sustaining layer includes graphite oxide.

16. The semiconductor device of claim 14, wherein a thickness of the sustaining layer is between 2 angstroms and 100 angstroms.

17. The semiconductor device of claim 14, wherein the sustaining layer maintains a height in the air gap that is same with a height of the conductive feature.

18. The semiconductor device of claim 14, wherein a top surface of the sustaining layer is not coplanar with a top surface of the conductive feature.

19. The semiconductor device of claim 14, further comprising a capping layer having two opposite wall portions covering opposite side surfaces of the conductive feature.

20. The semiconductor device of claim 19, wherein a top surface of the sustaining layer is not coplanar with a top surface of the two opposite wall portions.
